(19) United States
(12) Patent Application Publication
(10) Pub. No.: US 2006/0032525 A1
(43) Pub. Date: Feb. 16, 2006

(54) Boron carbide films with improved thermoelectric and electric properties

(76) Inventors: Larry C. Olsen, Richland, WA (US); Peter M. Martin, Kennewick, WA (US)

Correspondence Address: Douglas E. McKinley, Jr.;McKinley Law Office, P.O. Box 202, Richland, WA, 99352, US

(21) Appl. No.: 10/917,813

(22) Filed: Aug. 13, 2004

(51) Int. Cl. H01L 35/28; H01L 23/38

(52) U.S. Cl. 136/203; 136/205; 257/930

(57) ABSTRACT

A p-type semiconductor material with enhanced thermoelectric and electric properties comprising alternating thin films of boron carbide having a dopant selected from the group of Ge and Si. Alternating layers of boron carbide are of the general form BₓC_{y} with B₄C and B₉C being preferred. Layers are formed by sputter depositing. The dopant is provided in the layers by co-sputtering the dopant with the boron carbide. Alternatively, the dopant may be provided by diffusing the dopant into the deposited boron carbide layers. Layers are formed on a substrate that is heated to a temperature of between about 400° C. and about 600° C. The alternating layers of boron carbide are heat treated at a temperature of about 900° C.-1000° C. for a period of about 1 hour to form a polycrystalline structure.

### STATEMENT REGARDING FEDERALLY SPONSORED RESEARCH OR DEVELOPMENT

This invention was made with Government support under Contract DE-AC0676RLO1830 awarded by the U.S. Department of Energy. The Government has certain rights in the invention.

### CROSS-REFERENCE TO RELATED APPLICATIONS

Not Applicable

### BACKGROUND OF THE INVENTION

Thermoelectric materials, consisting generally of a p-type material and an n-type material wherein a temperature difference across the p-n couple causes heat and charge carriers to flow as a result of the Seebeck effect, are well known and have found broad applicability in a variety of industrial uses. A measure of the power conversion effectiveness of a thermoelectric material is the figure of merit ZT=(S²σ/κ)T, where S is the Seebeck coefficient, σ is the electrical conductivity and T is the absolute temperature. An exemplary thermoelectric module consisting of a p type leg and n-type leg is shown in FIG. 1. A temperature difference across the p-n couple causes heat and charge carriers to flow as a result of the Seebeck effect, and power is generated when connected to an external circuit. The efficiency of such a system depends on the electrical and thermal conductivity, and the Seebeck coefficient of the material/structure. The ideal efficiency of a thermoelectric converter can be expressed as a function of the dimensionless parameter ZT and the temperature difference between hot and cold junctions of a thermoelectric device. FIG. 2 shows the theoretical relationship between thermoelectric efficiency, ZT, and temperature difference between the hot and cold junctions.

Recently, advances in the electric and thermoelectric properties of the materials used to manufacture thermoelectric devices have led to a desire to utilize these materials in the harvesting and recovery of energy from waste heat in a variety of industrial, commercial, and even consumer applications. For example, assuming a thermoelectric device of sufficient efficiency, waste heat from virtually any heat source, including but not limited to exhaust gases from vehicles (particularly heavy vehicles), fuel cells, gas turbines, industrial processes, and reactor systems, could potentially be utilized to produce useful amounts of electricity, enhancing the efficiency of these devices. Conversely, thermoelectric cooling accomplished as a result of the Peltier effect could be used to remove heat, for example, from electrical devices and for refrigeration.

In the last decade, new materials and structures with increased values of the material figure of merit, ZT, have been developed for thermoelectric energy conversion and cooling. Whereas the ZT values for thermoelectric materials exceeding 1.0 where apparently unattainable from 1970 to 1990, values greater than 2.0 were reported in the 1990s by Rama Venkatasubramanian, Edward Siivota, Thomas Colpitts and Brooks O'Quinn in the article “Thin-film thermoelectric devices with high room-temperature figures of merit” Nature, 413, 11 Oct. 2001, 597-602. The entire contents of this, and all other patents, publications, papers, and references are incorporated herein in their entirety as if written in full by this reference. The increased values for ZT indicate that efficiencies greater than 20% and coefficient of performance values greater than 2 are possible for power production and refrigeration, respectively. Low dimensional structures also show promise for improved thermoelectric performance and power conversion efficiencies. Some of the most encouraging results have been achieved for thin film superlattice and quantum well structures as described in T. Koga, A. Sun, S. B. Cronin and M. S. Dresselhaus, Applied Physics Letters, 73(20) (1998) 2950-2952, L. D. Hicks and M. S. Dresselhaus, Phys. Rev. B47 19 (1993) 12 727-73 1, and S. Ghamaty and N. Elsner, Proceedings of the International Conference on Thermoelectrics (1999), 18th 485-488.

Unfortunately, while recent advances in the techniques and materials used to form thermoelectric devices have been shown to produce materials with enhanced efficiency, typically the increased efficiency remains insufficient to justify the cost of these systems on an economic basis. This is a result of both the efficiency of these devices and fabrication techniques used in achieving these advances in thermoelectric materials, which are both time consuming and expensive.

For example, both U.S. Pat. No. 5,436,467 entitled “Superlattice Quantum Well Thermoelectric Material” and U.S. Pat. No. 5,550,387 “Superlattice Quantum Well Structure” describe a method for using electron beam evaporation sources to form crystalline structures in a molecular beam epitaxy. As described in U.S. Pat. No. 5,436,467, this technique forms “superlattice quantum well thermoelectric material using elements for the layers all of which have the same crystalline structure.” The technique suffers from the drawback that operating molecular beam epitaxy on a large scale is both prohibitively slow and expensive. U.S. Pat. No. 6,096,965 entitled “Quantum Well Thermoelectric Material on Organic Substrate” and U.S. Pat. No. 6,096,964 “Quantum Well Thermoelectric Material on Thin Flexible Substrate” each describe methods of forming crystalline silicon and silicon-germanium layers using a magnetron sputtering system and doping with boron to produce a p-type layer. While magnetron sputtering is more amenable to cost effective scale up, the materials described in these patents have not shown efficiencies that would justify their use in industrial applications.

Thus, virtually all structures to date have been deposited by molecular beam epitaxy (MBE) and magnetron sputtering on a small scale. In additional to the technical challenges, two major factors that are critical to a functional device have yet to be demonstrated. The first is the need for a cost effective deposition process; the deposition process currently being used is too slow, costly and unscaleable. Quantum well structures may have thicknesses up to 100 μm. Use of MBE to deposit these structures would be exceedingly cumbersome and lengthy. The other major factor holding up this technology, however, is the demonstration of scaled-up quantum well devices with performance comparable to those reported for small scale. Current devices have a surface area of only one cm².

Thus, there remains a need for materials and methods that allow the formation of highly efficient thermoelectric devices on a large scale for industrial application.

### BRIEF SUMMARY OF THE INVENTION

Accordingly, it is an object of the present invention to provide a p-type semiconductor material with enhanced thermoelectric and electric properties and a method of making a p-type semiconductor material with enhanced thermoelectric and electric properties that may be reliably and inexpensively manufactured on a large scale. It is a further object of the present invention to provide a thermoelectric device comprising at least one layer of an n-type semiconductor material and at least one layer of a p-type semiconductor material wherein the p-type semiconductor material exhibits enhanced thermoelectric and electric properties that may be reliably and inexpensively manufactured on a large scale. These and other objects of the present invention are accomplished by a method of making a p-type semiconductor material comprising alternating thin films of boron carbide materials having a dopant selected from the group of Ge and Si. Preferably, while not meant to be limiting, the alternating layers of boron carbide are selected as B₄C and B₉C, although any boron carbide material of the general form BₓC₁₃₋ₓ is suitable and should be considered as falling within the scope of the invention.

As will be shown, the alternating layers of boron carbide formed by the present invention are treated such that they may form in a polycrystalline structure. The amount of dopant is selected to maximize the enhanced thermoelectric and electric properties of the resultant material, but generally comprises between about 0.01 atomic percent and about 2 atomic percent of the thin films. Generally, the method of manufacturing a p-type semiconductor materials of the present invention performs the steps of sputter depositing alternating layers of a thin film of boron carbide and providing a dopant in the layers selected from the group of Ge and Si. Preferably, and not meant to be limiting, the dopant is provided in the layers by co-sputtering the dopant with the boron carbide. Alternatively, the dopant may be provided by diffusing the dopant into the deposited boron carbide layers. Preferably, and not meant to be limiting, the layers are formed on a substrate that is heated to a temperature of between about 400° C. and about 600° C. The resultant thin films are then further heat treated. Generally, while not meant to be limiting, the p-type semiconductor materials of the present invention most effectively form the polycrystalline phase which is believed by the inventors to be at least partially responsible for the enhanced thermoelectric and electric properties when the sputter deposited thin films are heat treated at a temperature of about 900° C.-1000° C. for a period of about 1 hour.

### BRIEF DESCRIPTION OF THE SEVERAL VIEWS OF THE DRAWING

FIG. 1 is a schematic drawing of a typical p-n thermoelectric power generating/cooling module.

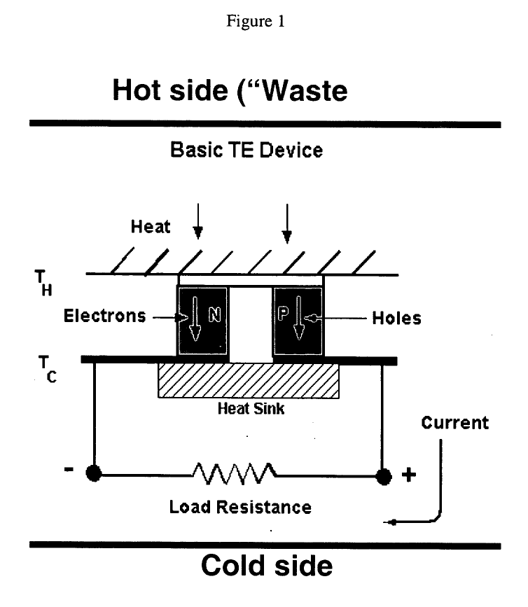

FIG. 2 is a graph showing the theoretical efficiency versus figure of merit ZT.

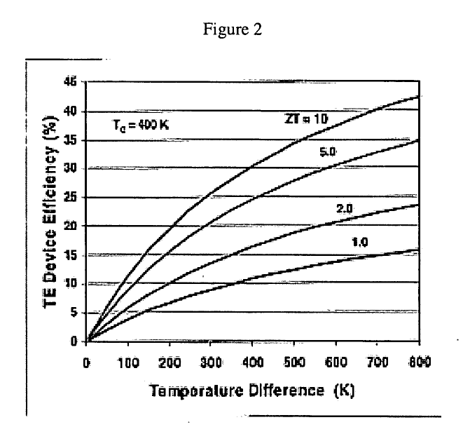

FIG. 3 is a graph summarizing performance results for small scale depositions, plotting measured absolute Seebeck coefficient against conductivity. Also shown in the figure are asymptotic curves for a range of power factor values, where this quantity is given by S²σT.

FIG. 4 is a graph summarizing the thermoelectric properties of all single layer films and quantum wells, including scaled up depositions.

### DETAILED DESCRIPTION OF THE INVENTION

A series of experiments using magnetron sputtering were conducted to demonstrate the present invention. These experiments took place in two phases: (1) demonstration and replication of quantum well films on a small scale and (2) quantum well film process scale up. The objective of Phase 1 was to establish a baseline for the scaled up process in Phase 2 and to compare thermoelectric properties with results reported by others.

In Phase 1 Si/Si_{0.8}Ge_{0.2} and B₄C/B₉C quantum well films were deposited onto one inch diameter single crystal Si substrates in a small box coater, described in P. M. Martin, L. C. Olsen, “Proceedings of the 46^{th} Annual Technical Conference of the Society of Vacuum Coaters” (2003) 126-129. A rotating substrate holder was placed 15 cm above the Si and Si_{0.8}Ge_{0.2} or B₄C and B₉C sputtering targets. While the substrate could be heated to temperatures as high as 800° C., depositions were performed at ambient (88° C.), 200° C., 300° C., 400° C., and 600° C. for the Si and SiGe films, and 88° C., 400° C., 500° C., 600° C. and 800° C. for BC films. Additional samples of a single layer of B₉C on a Si substrate and B on a Sapphire substrate were also prepared. Substrate temperature was measured by thermocouples placed at each substrate position. The target diameter was 15.2 cm. RF power densities applied to the sputtering targets ranged from 1.1 W/cm² to 3.3 W/cm². All depositions used high purity Ar as the sputtering gas. Deposition rates depended on power applied to the sputtering target, substrate target separation, gas pressure and substrate temperature, and ranged from 1 Å/s to 6 Å/s for Si and SiGe films and ˜0.13 Å/s for BC films.

Quantum well depositions were performed by moving the substrate sequentially from over the one target (Si or B₄C) and then over the other (Si_{0.8}Ge_{0.2} or B₉C) target. Before deposition, the substrate was heated to the required temperature by a resistive heater. The first layer deposited was the high band gap material (Si or B₄C) layer. Each layer was ˜100 Å thick. Thickness was determined simply by time of deposition. For initial evaluations, 100-300-layer quantum well structures were deposited onto single crystal Si substrates. The electrical conductivity of the quantum well structures and single layer films was measured by the four point van der Pauw technique and the Seebeck coefficient (thermopower) was measured by applying a temperature gradient across the sample and measuring the voltage across the sample. All measurements were in-plane. The Seebeck coefficient and conductivity of the substrate were measured before and after deposition. The Seebeck coefficient and conductivity of the film were calculated using standard techniques as described in S. Ghamaty and N. Elsner, Proceedings of the International Conference on Thermoelectrics (1999), 18th 485-488.

In Phase 2, the deposition process was scaled up to deposit quantum well structures on twelve 10 cm Si wafers or substrate areas of 0.5 m². The following chamber modifications were made to scale up the deposition process; four quartz heaters were placed above the substrate holder to achieve uniform heating over an area of 0.5 m², shields were placed between the sputtering cathodes to prevent cross talk, a precision stepper motor was attached to the substrate rotation assembly for precise thickness control, and both sputtering cathodes were in continuous operation.

In this configuration, the substrate holder rotated continuously over the sputtering targets with the rotation rate and deposition rate tuned for each target to obtain a layer thickness of 100 Å. This deposition geometry posed several concerns. The major concern was that the crystal orientation and the resulting thermoelectric properties would degrade due to the increased angles of incidence of the sputtered atoms and associated shadowing. Other concerns were the extent of cross talk between cathodes, uniformity of coverage and the overall robustness of the system with thermal cycling.

Single layer Si and Si_{0.8}Ge_{0.2} films and Si/Si_{0.8}Ge_{0.2} quantum well structures with the highest electrical conductivity, highest Seebeck coefficient and largest value of power factor (S²σ) were deposited at a substrate temperature of 400° C. Single layer B₄C and B₉C films had highest electrical conductivity and Seebeck coefficient when deposited between 500° C. and 600° C. The results for B₄C/B₉C quantum well structures and comparative structures are given below in Table 1. All samples contained Ge doping.

TABLE 1
Results for B-C films

| | | | Seebeck | |
|---|---|---|---|---|
| Sample | | Conductivity | Coeff | Power |
| T = 300° K | Process | (Ohm-cm)⁻¹ | (μV/° C.) | Factor |
| A | Single Boron | 35 | 340 | 0.0012 |
| | Layer on Si | | | |
| | substrate at 600° C. | | | |
| A | Single Boron | 1660 | 223 | 0.025 |
| | Layer on Si | | | |
| | substrate at | | | |
| | 600° C. w/ heat | | | |
| | treatment at 1000° C. | | | |
| B | 40 alternating layers of | 2560 | 201 | 0.031 |
| | B₄C/B₉C on | | | |
| | Si substrate at | | | |
| | 600° C. | | | |
| | w/ heat treatment | | | |
| | at 1000° C. | | | |
| C | 20 alternating layers of | 4160 | 235 | 0.070 |
| | B₄C/B₉C on | | | |
| | Si substrate at | | | |
| | 600° C. w/ | | | |
| | additional Ge doping | | | |
| D | Single Boron Layer on | 118 | 170 | 0.001 |
| | Sapphire substrate | | | |

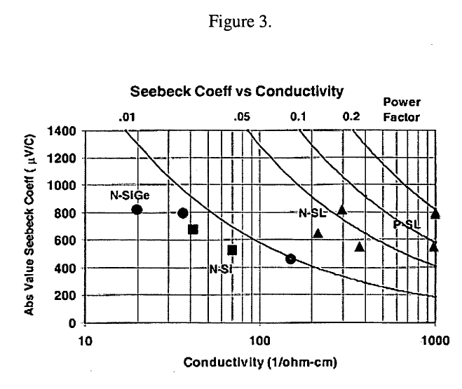

FIG. 3 summarizes performance results for small scale depositions, by plotting measured absolute Seebeck coefficient against conductivity. Also shown in the figure are asymptotic curves for a range of power factor values, where this quantity is given by S²σT. Typical values of S were ˜800 μV/K, σ between 100 and 1000 (Ω.cm)⁻¹ and power factors between 0.01 and 0.20. The values shown in FIG. 3 are comparable or better than those previously reported for MBE-deposited and sputter-deposited quantum wells. These experiments demonstrated success in depositing both n-type, and for the first time reported in the literature, p-type Si/Si_{0.8}Ge_{0.2} quantum well structures. In contrast to the literature, it was also possible to deposit n-type B₄C and B₉C films.

It is difficult to speculate on the reasons for the improved thermoelectric properties of the magnetron-sputtered quantum wells. It was important, however, to preserve the electric properties (carrier concentration, mobility) while minimizing the thermal conductivity of the quantum wells. The improvements might be due to enhanced acoustic phonon scattering at interfaces and grain boundaries.

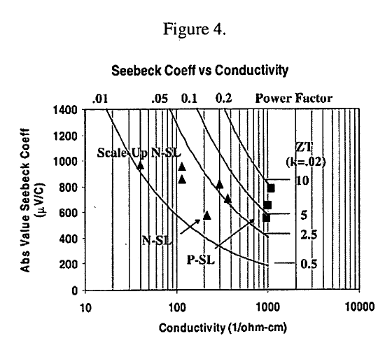

FIG. 4 summarizes the thermoelectric properties of all single layer films and quantum wells, including scaled up depositions. Both FIGS. 3 and 4 demonstrate the effects of quantum confinement as predicted by Hicks and Dresselhaus; i.e., the power factors of quantum well structures are significantly higher than those of single layer films. Note that the power factor of single layer B₄C and B₉C films are in the range of the Si/Si_{0.8}Ge_{0.2} quantum wells. Thus, with quantum confinement effects, B₄C/B₉C quantum well structures should have power factors significantly higher than those of the single layer films. Thermoelectric properties (Seebeck coefficient) of single layer films and the quantum wells were essentially the same as those of the small scale films, but the conductivity was as much as an order of magnitude less than the best films. This decrease in conductivity might have been due to increased impurities in the films. While the deposition rates were the same as small scale films, the heating of a 0.5 m² substrate also heated the sides of the deposition chamber. As a result, gases evolved from the chamber walls and shielding that could have degraded electrical properties. A pre-deposition bake out at 400° C. and an over night pump down were required to eliminate contaminants in the chamber. With the fully-automated scaled up process, there is theoretically no limit on the number of layers that can be deposited.

### CLOSURE

While a preferred embodiment of the present invention has been shown and described, it will be apparent to those skilled in the art that many changes and modifications may be made without departing from the invention in its broader aspects. The appended claims are therefore intended to cover all such changes and modifications as fall within the true spirit and scope of the invention.

We claim:

1) A p-type semiconductor material with enhanced thermoelectric and electric properties comprising alternating thin films of boron carbide materials having a dopant selected from the group of Ge and Si.

2) The p-type semiconductor material of claim 1 wherein said alternating layers of boron carbide are selected as having the general formula BₓC₁₃₋ₓ.

3) The p-type semiconductor material of claim 1 wherein said alternating layers of boron carbide are selected as B₄C and B₉C.

4) The p-type semiconductor material of claim 1 wherein said alternating layers of boron carbide are in a polycrystalline structure.

5) The p-type semiconductor material of claim 1 wherein said dopant comprises between about 0.01 atomic percent and about 2 atomic percent of said thin films.

6) A thermoelectric device comprising at least one layer of an n-type semiconductor material and at least one layer of a p-type semiconductor material wherein said p-type semiconductor material comprises alternating thin films of boron carbide materials having a dopant selected from the group of Ge and Si.

7) The thermoelectric device of claim 6 wherein said alternating layers of boron carbide of said p-type semiconductor material are selected as having the general formula BₓC₁₃₋ₓ.

8) The thermoelectric device of claim 6 wherein said alternating layers of boron carbide of said p-type semiconductor material are selected as B₄C and B₉C.

9) The thermoelectric device of claim 6 wherein said alternating layers of boron carbide of said p-type semiconductor material are in a polycrystalline structure.

10) The thermoelectric device of claim 6 wherein said dopant in said alternating layers of boron carbide of said p-type semiconductor material comprise between about 0.01 atomic percent and about 2 atomic percent of said thin films.

11) A method of manufacturing a p-type semiconductor material with enhanced thermoelectric and electric properties comprising the steps of:
a. sputter depositing at least one layer of a thin film of boron carbide on a substrate
b. providing a dopant in said layer selected from the group of Ge and Si.

12) The method of claim 11 wherein alternating thin film layers of boron carbide, each of said thin film layers containing a dopant selected from the group of Ge and Si, are sputter deposited on said substrate, thus forming said p-type semiconductor material.

13) The method of claim 12 wherein alternating thin film layers of boron carbide are selected as having the general formula BₓC₁₃₋ₓ.

14) The method of claim 12 wherein alternating thin film layers of boron carbide are selected as B₄C and B₉C.

15) The method of claim 11 wherein alternating thin film layers of boron carbide are deposited on a substrate heated to a temperature of between about 400° C. and about 800° C.

16) The method of claim 11 wherein the step of providing a dopant is performed by co-sputtering the dopant with the boron carbide.

17) The method of claim 11 wherein the step of providing a dopant is performed by diffusing the dopant into the deposited boron carbide layer.

18) The method of claim 11 wherein the step of sputter depositing said layer of thin film boron carbide is performed at a substrate temperature of between about 400° C. and about 800° C.

19) The method of claim 11 further comprising the step of heat treating the p-type semiconductor material at a temperature of about 900° C.-1000° C.
